(19) United States
(12) Patent Application Publication
(10) Pub. No.: US 2010/0151616 A1
(43) Pub. Date: Jun. 17, 2010

(54) DYE-SENSITIZED SOLAR CELL

(75) Inventors: Ryuichi SHIRATSUCHI, Fukuoka (JP); Shuzi Hayase, Fukuoka (JP)

Correspondence Address: SUGHRUE MION, PLLC, 2100 PENNSYLVANIA AVENUE, N.W., SUITE 800, WASHINGTON, DC, 20037, US

(73) Assignee: KYUSHU INSTITUTE OF TECHNOLOGY, FUKUOKA (JP)

(21) Appl. No.: 12/711,694

(22) Filed: Feb. 24, 2010

Related U.S. Application Data
(62) Division of application No. 11/183,895, filed on Jul. 19, 2005.

(30) Foreign Application Priority Data
Jul. 20, 2004 (JP) 2004-212008

(51) Int. Cl. H01L 31/18; H01L 31/0224; H01L 31/04

(52) U.S. Cl. 438/69; 257/E31.126

(57) ABSTRACT

A dye-sensitized solar cell is provided that includes a transparent electrode formed by depositing, in order on a transparent substrate, a transparent conductive film containing tin oxide as a main component, and a compact titanium oxide layer and/or a porous titanium oxide layer, wherein the transparent conductive film, which contains tin oxide as the main component, has a fluorine concentration not exceeding 0.2 wt %, and the transparent conductive film on the transparent substrate has in an X-ray diffraction pattern thereof diffraction peaks attributable to (110), (200), and (211) planes satisfying the conditions that, relative to the sum of the diffraction intensities of the three planes, the ratios of both the (110) and (211) diffraction intensities are larger than 0.25 and smaller than 0.4, and the ratio of the (200) diffraction intensity is larger than 0.25 and smaller than 0.5. The dye-sensitized solar cell has high light conversion efficiency and has an FTO film that are highly heat resistant and does not easily deteriorate during a thermal treatment step when forming a titanium oxide porous film.

### CROSS REFERENCE TO RELATED APPLICATION

This is a divisional of application Ser. No. 11/183,895 filed Jul. 19, 2005, the disclosure of which is incorporated by reference.

### BACKGROUND OF THE INVENTION

1. Field of the Invention

The present invention relates to a solar cell employing porous oxide semiconductor microparticles and, in particular, to a dye-sensitized solar cell.

2. Description of the Related Art

Instead of using a silicon semiconductor, a dye-sensitized solar cell having, as a solar cell, an electrochemical cell structure by way of an iodine solution, etc. is known. As an electrode, on the side on which light is incident, used for the dye-sensitized solar cell, there has been a desire for a transparent conductive material having high transmittance and low sheet resistance. A tin-doped indium oxide (ITO) film has conventionally been used in many applications as an electrode material that satisfies these conditions. However, ITO has the defect that the stability during a thermal treatment in a process for fabricating a porous film in a dye-sensitized solar cell is poor. Furthermore, it has been found that, in a fluorine-doped tin oxide (FTO) film, a low specific resistance on the order of 3.5×10⁻⁴ (Ωcm) can be obtained, and this material has started to be widely used as a transparent electrode for a dye-sensitized solar cell (ref. Japanese unexamined patent application publication Nos. 1-236525, 2-181473, 2-231773, 11-109888, 2000-156514, and 2003-151355).

When fabricating a dye-sensitized solar cell, it is necessary to form a porous oxide film. Such an oxide film is usually formed on top of a transparent conductive film containing tin oxide as a main component on top of a transparent substrate by a film formation method such as a screen printing method or a squeegee method using a paste comprising titanium oxide microparticles, or an electrodeposition method involving electrodeposition of a titanium oxide precursor, followed by a method in which the resulting film is sintered at a temperature equal to or lower than the softening point of the substrate. However, there is the problem that during the film formation and sintering, the resistance of the tin oxide film increases due to some interaction with the paste or the titanium oxide precursor.

### BRIEF SUMMARY OF THE INVENTION

It is therefore an object of the present invention to obtain a high efficiency dye-sensitized solar cell by providing an FTO film that is highly heat resistant and does not easily deteriorate during a thermal treatment step when forming a titanium oxide porous film.

This object of the present invention can be accomplished by a dye-sensitized solar cell comprising a transparent electrode comprising a transparent substrate, a transparent conductive film applied on top of the transparent substrate, the transparent conductive film comprising tin oxide as a main component, and a compact titanium oxide layer and/or a porous titanium oxide layer applied on top of the transparent conductive film, (1) the transparent conductive film, which comprises tin oxide as the main component, having a fluorine concentration not exceeding 0.2 wt %, and (2) the transparent conductive film having in an X-ray diffraction pattern thereof diffraction peaks attributable to (110), (200), and (211) planes satisfying conditions (a) and (b) below.

(a) The ratios of both the (110) and (211) diffraction intensities relative to the sum of the diffraction intensities of the three planes being larger than 0.25 and smaller than 0.4.
(b) The ratio of the (200) diffraction intensity relative to the sum of the diffraction intensities of the three planes being larger than 0.25 and smaller than 0.5.

In the case of a dye-sensitized solar cell employing FTO in a transparent electrode, if the concentration of fluorine in an FTO film is equal to or less than 0.2 wt %, it is possible to suppress the adverse effect of diffusion of fluorine into a titanium oxide layer to a substantially negligible level. In addition to this, by setting diffraction peaks attributable to (110), (200), and (211) planes in an X-ray diffraction pattern of a transparent conductive film on a transparent substrate so as to have an intensity in a predetermined range, it is possible to obtain a solar cell having excellent characteristics compared with conventional solar cells.

### BRIEF DESCRIPTION OF DRAWING

FIG. 1 is a diagram showing SIMS profiles of titanium, tin, and chlorine in the depth direction from a titanium oxide surface to a tin oxide layer in a transparent electrode of Comparative Example 6 in Table 1.

### DETAILED DESCRIPTION OF THE INVENTION

As a result of an investigation by the present inventors into various physical properties of an FTO film (tin oxide film) and characteristics of a dye-sensitized solar cell, it has been found that the amount of fluorine in the FTO film, which is added to the film in order to impart electrical conductivity thereto, has a large influence on the characteristics of the dye-sensitized solar cell. Conventionally used transparent conductive films containing tin oxide as a main component contain, in order to reduce the resistance of the film, excess fluorine in the film over that which contributes to the electrical conductivity. However, the presence of excess dopant (fluorine) causes the light transmittance to deteriorate and has an adverse influence on improvement of the characteristics of the dye-sensitized solar cell. Furthermore, the excess fluorine might diffuse into a titanium oxide film applied on a transparent conductive film during a thermal treatment, thereby similarly having an adverse influence on the improvement of the characteristics of the dye-sensitized solar cell.

With regard to a dye-sensitized solar cell having a transparent electrode comprising, in order on a transparent substrate, a transparent conductive film comprising tin oxide as a main component, and a compact titanium oxide layer, and/or a porous titanium oxide layer, the present inventors have further found that one of the conditions for obtaining a dye-sensitized solar cell being excellent in characteristics such as conversion efficiency is to set the concentration of fluorine in the transparent conductive film comprising tin oxide as the main component not to exceed 0.2 wt %.

The present inventors have also found that the crystal orientation of the FTO film has a large influence on the characteristics of the dye-sensitized solar cell. Conventional FTO films, which have a preferential (200) plane orientation, have the defect of poor light transmittance although the surface has little unevenness and the resistance is low. FTO films with a preferential (110) and (211) plane orientation have a very uneven surface and are unsuitable for use in the formation of a film of titanium oxide microparticles. It has therefore been found that, when the orientation of each plane is extremely strong, this exerts an adverse influence on the characteristics of the dye-sensitized solar cell.

According to an investigation by the present inventors, it has been found that, with respect to diffraction peaks attributable to (110), (200), and (211) planes in an X-ray diffraction pattern of the FTO film on the transparent substrate, by satisfying the conditions that the ratios of both the (110) and (211) diffraction intensities relative to the sum of the diffraction intensities of the three planes are larger than 0.25 and smaller than 0.4, and that the ratio of the (200) diffraction intensity relative to the sum of the diffraction intensities of the three planes is larger than 0.25 and smaller than 0.5, it is possible to obtain a dye-sensitized solar cell being excellent in characteristics such as conversion efficiency.

As long as the above-mentioned two requirements are satisfied, that is, (1) to set the concentration of fluorine in the transparent conductive film comprising tin oxide as the main component not to exceed 0.2 wt %, and (2) to set the diffraction intensity of diffraction peaks from each of the (110), (200), and (211) planes in an X-ray diffraction pattern of the FTO film on the transparent substrate to be in a predetermined range, characteristics such as conversion efficiency are synergistically improved, and a particularly excellent dye-sensitized solar cell of the present invention can be obtained.

The present inventors have also found that chlorine originating from a starting material of the FTO film remains in the FTO film, and that the behavior of the chlorine has a large influence on the characteristics of the dye-sensitized solar cell. Conventional transparent conductive films are doped with fluorine in the film in order to decrease the resistance thereof, but chlorine originating from a starting material might remain in the film without being decomposed during a pyrolysis reaction. Since chlorine itself contributes to the electrical conductivity, no problem arises during normal applications, but it has been found that there is a possibility that, on contact with titanium oxide and during a subsequent thermal treatment, chlorine might diffuse into a titanium oxide film. Such diffusion of chlorine into titanium oxide causes a new energy level to be formed, thus exerting an adverse influence on the characteristics of the dye-sensitized solar cell. In the present invention, it is therefore preferable that there is substantially no diffusion into the titanium oxide layer of chlorine remaining in the transparent conductive film comprising tin oxide as the main component. Such a film can be formed by appropriately adjusting the conditions under which the film is formed.

In such a case, if the conditions are met that the concentration of fluorine in the transparent conductive film comprising tin oxide as the main component does not exceed 0.2 wt % and that the X-ray diffraction intensities of the transparent conductive film satisfy the above-mentioned relationships, and a further condition that there is substantially no diffusion into the titanium oxide layer of chlorine remaining in the transparent conductive film comprising tin oxide as the main component is also satisfied, a dye-sensitized solar cell having yet further excellent performance can be obtained. ‘Substantially no diffusion’ means that, when the abundance ratio of the titanium oxide layer to the tin oxide layer is 1:1, the ratio (C2/C1) of the chlorine concentration (C2) where the titanium oxide to tin oxide abundance ratio is 1:1 to the chlorine concentration (C1) in the bulk tin oxide is less than 0.5. Specifically, it is preferable for the concentration of chlorine in the titanium oxide layer to be equal to or less than 0.2 wt %.

In the present invention, the transparent conductive film comprising tin oxide as the main component preferably has a thickness in the range of 0.3 to 1.0 μm. With regard to a process for forming a film, it is preferable that the transparent conductive film comprising tin oxide as the main component is adhered to a transparent substrate by a pyrolytic oxidation reaction.

The concentrations of fluorine and chlorine in the FTO film may be determined by an electron probe microanalyzer (EPMA). The profile in the depth direction of the film may be determined by a secondary ion mass spectrometer (SIMS). The FTO crystal orientation may be determined by an X-ray diffractometer. In the case of tin oxide, the main peaks appearing in an X-ray diffraction pattern are attributable, in order of increasing diffraction angle, to (110), (101), (200), (211), (220), (310), and (301) planes. Among these, it is the (110), (200), and (211) planes that give peaks with a particularly large intensity, and these diffraction peak intensity values can be used as a guideline for FTO crystal orientation.

When dye-sensitized solar cells are formed by changing the fluorine concentration in the tin oxide film so as to investigate the conversion efficiency, it is found that solar cells having a relatively small fluorine content exhibit high efficiency. Furthermore, chlorine, which is an undecomposed residue of a starting material, can be detected by SIMS analysis, and it has been found that it is only when chlorine diffuses into the titanium layer that the solar cell efficiency is degraded. With regard to crystal planes of tin oxide by X-ray diffraction, in films that have a relatively strong (110) or (211) preferential orientation, the surface is very uneven, and the solar cell efficiency deteriorates. In the case of preferential (200) orientation, even if the preferential orientation is strong, since the surface is flat, the solar cell efficiency might be good. If the preferential orientation is too strong, it has been found that the conversion efficiency is degraded, which is thought to be due to degradation of the light transmittance.

With regard to a method for obtaining an FTO transparent conductive film, there are various methods such as a spray method, a CVD method, a sputtering method, or a dip method, and among these methods the spray method and the CVD method give a film having excellent characteristics, and both are also economical and are widely used as film formation methods. As a tin starting material used in these methods, SnCl₄, (CₙH₂ₙ₊₁)₄Sn (here, n=1 to 4), C₄H₉SnCl₃, (CH₃)₂SnCl₂, etc. are generally used. As a starting material used for doping with fluorine, in the case of the spray method NH₄F is often used, and in the case of the CVD method HF, CCl₂F₂, CHClF₂, CH₃CHF₂, CF₃Br, etc. are often used.

When an FTO film is formed using these starting materials, the amount of fluorine in the film may be varied by changing the proportion of the dopant starting material introduced according to the film formation conditions. With regard to the film formation conditions, in addition to the above conditions, the temperature of the substrate during film formation and the amount of water, which is an oxidizing agent, are also important. Although the reaction mechanism is not yet clear, it is surmised that the amounts of fluorine and chlorine in the film are strongly related to dissociation of chlorine originating from a starting material by a hydrolysis reaction. Control of the crystal planes may also be achieved by controlling the oxygen oxidation reaction and the hydrolysis reaction.

### EXAMPLES

The present invention is explained in detail below by reference to Examples. In the Examples, the sheet resistance was measured using a four-terminal resistance meter. The short-circuit current ratio is a value expressed by (short-circuit current of improved product)/(short-circuit current of conventional product). The open-circuit voltage ratio is a value expressed by (open-circuit voltage of improved product)/(open-circuit voltage of conventional product). The F.F ratio is a value expressed by (F.F of improved product)/(F.F of conventional product). The conversion efficiency was measured using a picoammeter and a DC stabilized power supply having a potential sweep function. All these values are expressed as a relative value when the performance of a conventional product (a film that was formed by a reaction using mainly oxygen in the air, resulting in the contents of fluorine and chlorine in the film not being appropriately controlled and both exceeding 0.2 wt %, and the crystal therefore having a preferential (200) orientation) is defined as 1.

### Examples 1 to 4, and Comparative Examples 1 to 6

A piece of borosilicate glass having dimensions of 30 mm×30 mm and a thickness of 1 mm was washed and dried well, thus giving a glass substrate. A transparent conductive film was formed on top of this substrate as follows. Ammonium fluoride was added to a solution of n-butyl tin trichloride in a mixture of water and ethanol, and an FTO film was fabricated by a spray method using a mixed gas of nitrogen gas and oxygen gas, while changing the mixing ratio of water and ethanol, the mixing ratio of nitrogen gas and oxygen gas, and the temperature at which the glass was heated. The FTO films thus obtained had a film thickness of 0.36 to 0.9 μm and a sheet resistance of 6.1Ω/□ to 13.4Ω/□. The amount of fluorine in the transparent conductive films was quantitatively measured using an EPMA, and the results are given in Table 1.

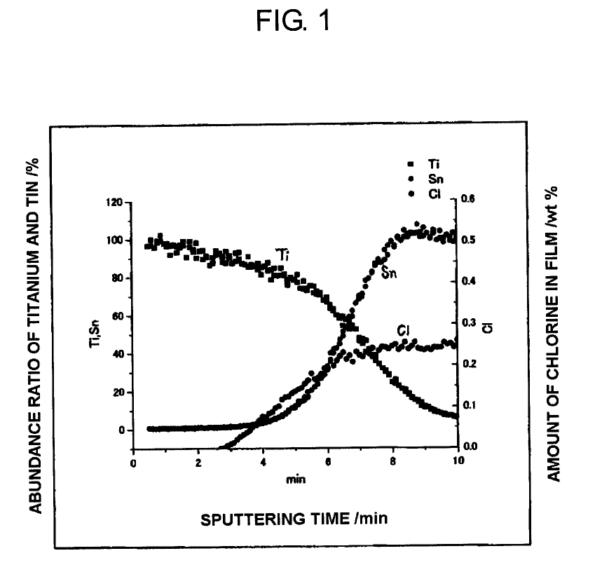

In the FTO films obtained above, the amount of chlorine that had diffused into the titanium oxide layer was measured, and the results are also given in Table 1. FIG. 1 shows a profile of chlorine in the depth direction by SIMS for a sample of Comparative Example 6 in Table 1. It also shows profiles of titanium and tin in the depth direction from the titanium oxide surface (the film thickness was made 1 μm or less to make the measurement possible) to the tin oxide layer by SIMS for the sample of Comparative Example 6. The abundance ratios of titanium and tin are expressed as %, and chlorine is expressed as a value converted into weight (wt) % using the EPMA results.

With regard to the FTO film obtained above, the crystal orientation of the film was measured by, X-ray diffraction, and the diffraction intensity ratios of the peaks attributable to the (110), (200), and (211) planes relative to the sum of the three peaks were calculated. The results are also given in Table 1.

The glass equipped with the FTO film thus obtained was washed and dried well, then coated with a paste of titanium oxide microparticles in an area of 0.5 cm×1 cm by a squeegee method, and subjected to a thermal treatment in an electric oven at 450° C. for 1 hour, thus forming a porous titanium oxide film. The porous film thus obtained had a thickness of approximately 16 μm. This porous film was immersed in an ethanol solution containing N3 dye (RuL₂(NCS)₂, L: 4,4′-dicarboxy-2,2′-bipyridine) for on the order of 13 hours, thus modifying the microparticles with the dye. This film was sealed using a 50 μm spacer with, as a counter electrode, ITO or FTO having a platinum film formed thereon by a sputtering method. An electrolyte adjusted to 250 mL of I₂ and 580 mM of t-BuPy in acetonitrile was poured into this cell, thus forming a cell.

The solar cell characteristics were measured by irradiation of the dye-sensitized solar cell with AM 1.5, 100 mW/cm² simulated sunlight using a solar simulator. Various characteristics of the solar cell such as conversion efficiency (values relative to those of a conventional product) are also given in Table 1.

TABLE 1

| | Example | | | | Comparative Example | | | | | |
|---|---|---|---|---|---|---|---|---|---|---|
| | 1 | 2 | 3 | 4 | 1 | 2 | 3 | 4 | 5 | 6 |
| Film thickness μm | 0.62 | 0.45 | 0.58 | 0.45 | 0.61 | 0.36 | 0.60 | 0.90 | 0.62 | 0.60 |
| Sheet resistance Ω/□ | 7.1 | 8.5 | 7.6 | 10.8 | 6.1 | 12.6 | 8.4 | 11.9 | 13.4 | 7.4 |
| (110) intensity ratio | 0.32 | 0.33 | 0.29 | 0.26 | 0.23 | 0.43 | 0.44 | 0.27 | 0.22 | 0.33 |
| (200) intensity ratio | 0.38 | 0.42 | 0.46 | 0.35 | 0.53 | 0.34 | 0.27 | 0.53 | 0.27 | 0.25 |
| (211) intensity ratio | 0.30 | 0.25 | 0.25 | 0.39 | 0.25 | 0.23 | 0.29 | 0.20 | 0.52 | 0.42 |
| Short-circuit current ratio | 1.01 | 1.00 | 1.05 | 0.95 | 1 | 1.00 | 1.01 | 1.03 | 1.02 | 0.94 |
| Open-circuit voltage ratio | 1.01 | 1.03 | 1.04 | 1.04 | 1 | 1.03 | 1.01 | 1.00 | 1.01 | 1.00 |
| F.F ratio | 1.07 | 1.07 | 1.04 | 1.08 | 1 | 0.95 | 0.98 | 0.88 | 0.93 | 1.06 |
| Conversion efficiency ratio | 1.08 | 1.10 | 1.14 | 1.07 | 1 | 0.98 | 0.99 | 0.91 | 0.96 | 0.99 |
| Fluorine concentration | 0.13 | 0.03 | 0.07 | 0.09 | 0.29 | 0.06 | 0.26 | 0.14 | 0.02 | 0.11 |
| Chlorine concentration | 0.17 | 0.10 | 0.09 | 0.16 | 0.23 | 0.18 | 0.12 | 1.04 | 0.11 | 0.25 |

The dye-sensitized solar cell employing the transparent electrode of the present invention is excellent in solar cell characteristics such as conversion efficiency, and it is therefore expected to become widespread as a next-generation solar cell.

What is claimed is:

1. A method of manufacturing a dye-sensitized solar cell comprising a transparent electrode comprising:
applying a transparent conductive film on top of a transparent substrate, the transparent conductive film comprising tin oxide as a main component; and
applying a titanium oxide layer comprising a dye on top of the transparent conductive film, wherein the titanium oxide layer is a compact titanium oxide layer and/or a porous titanium oxide layer, thereby forming a dye-sensitized solar cell;
(1) the transparent conductive film, which comprises tin oxide as the main component, having a fluorine concentration not exceeding 0.2 wt %, and
(2) the transparent conductive film having in an X-ray diffraction pattern thereof diffraction peaks attributable to (110), (200), and (211) planes satisfying conditions (a) and (b) below:
(a) the ratios of both the (110) and (211) diffraction intensities relative to the sum of the diffraction intensities of the three planes being larger than 0.25 and smaller than 0.4, and
(b) the ratio of the (200) diffraction intensity relative to the sum of the diffraction intensities of the three planes being larger than 0.25 and smaller than 0.5.

2. The method according to claim 1, wherein the transparent conductive film comprising tin oxide as the main component further comprises chlorine, wherein the chlorine substantially does not diffuse into the titanium oxide layer.

3. The method according to claim 1, wherein the transparent conductive film comprising tin oxide as the main component has a thickness in the range of 0.3 to 1.0 μm.

4. The method according to claim 2, wherein the transparent conductive film comprising tin oxide as the main component has a thickness in the range of 0.3 to 1.0 μm.

5. The method according to claim 1, wherein the transparent conductive film comprising tin oxide as the main component is adhered to the top of the transparent substrate by a pyrolytic oxidation reaction.

6. The method according to claim 2, wherein the transparent conductive film comprising tin oxide as the main component is adhered to the top of the transparent substrate by a pyrolytic oxidation reaction.

7. The method according to claim 3, wherein the transparent conductive film comprising tin oxide as the main component is adhered to the top of the transparent substrate by a pyrolytic oxidation reaction.

8. The method according to claim 4, wherein the transparent conductive film comprising tin oxide as the main component is adhered to the top of the transparent substrate by a pyrolytic oxidation reaction.

9. The method according to claim 2, wherein the chlorine is present in the titanium oxide layer in a concentration less than or equal to 0.2 wt %.

10. The method according to claim 4, wherein the chlorine is present in the titanium oxide layer in a concentration less than or equal to 0.2 wt %.

11. The method according to claim 6, wherein the chlorine is present in the titanium oxide layer in a concentration less than or equal to 0.2 wt %.

12. The method according to claim 8, wherein the chlorine is present in the titanium oxide layer in a concentration less than or equal to 0.2 wt %.
